(19) United States
(12) Patent Application Publication
(10) Pub. No.: US 2025/0291013 A1
(43) Pub. Date: Sep. 18, 2025

(54) METHOD FOR PERFORMING A MAGNETIC RESONANCE MEASUREMENT COMPRISING MULTIPLE PARTIAL MEASUREMENTS

(71) Applicant: Siemens Healthineers AG, Forchheim (DE)

(72) Inventor: David Grodzki, Erlangen (DE)

(21) Appl. No.: 19/076,605

(22) Filed: Mar. 11, 2025

(30) Foreign Application Priority Data
Mar. 15, 2024 (DE) 10 2024 202 440.6

(51) Int. Cl. G01R 33/483; G01R 33/54

(52) U.S. Cl. CPC G01R 33/4835; G01R 33/543

(57) ABSTRACT

A method for performing a magnetic resonance measurement comprising multiple partial measurements, a magnetic resonance apparatus and a computer program product. According to the method, a first partial measurement is performed in a first period and a second partial measurement is performed after the first partial measurement. The second partial measurement involves the application of an excitation pulse for the excitation of a magnetic resonance signal. During the first period, at least part of a pulse calculation of the excitation pulse is performed.

### CROSS REFERENCE TO RELATED APPLICATIONS

This application claims the benefit of DE 10 2024 202 440.6 filed on Mar. 15, 2024, which is hereby incorporated by reference in its entirety.

### FIELD

The invention relates to a method for performing a magnetic resonance measurement comprising multiple partial measurements, a magnetic resonance apparatus and a computer program product.

### BACKGROUND

In medical technology, imaging by magnetic resonance (MR), also referred to as magnetic resonance imaging (MRI), is characterized by high soft tissue contrast. Radio-frequency (RF) pulses, for example excitation pulses, for generating a RF field gradient (also referred to as a B1 field) and gradient pulses for generating a magnetic field gradient are irradiated into an examination area in which an examination object is located with the aid of a magnetic resonance apparatus. The examination object may be a patient, for example. As a result, location-coded echo signals are triggered in the examination object, that are often also referred to as magnetic resonance signals. The magnetic resonance signals are received as measurement data by the magnetic resonance apparatus and used for the reconstruction of magnetic resonance images.

Often, mostly (>99%) more or less static RF transmission pulses are used for excitation or preparation, e.g. so-called sinc pulses, that only differ in phase, frequency, bandwidth and amplitude for a measurement.

In addition to these pulses, there are also so-called dynamic pulses, for example multi-channel or pTx pulses, that adapt to certain B0, B1 distributions and/or target states in the local area. For example, pTx pulses may be configured in such a way that they ensure uniform B1 distribution in the measurement volume or targeted excitation of patterns in the examination object.

However, the preparation of dynamic pulses may take quite a long time. They may take up to 30 seconds per partial measurement, in which one slice is measured at a time. With various known methods, this processing time may be reduced to a few seconds, however in the case of measurements with many slices or partial measurements, this may result in an unacceptably long processing time. In order to bypass the processing time completely, other methods dispense with the individuality of patient-specific pulses and use so-called universal pulses. These may be used without measuring preceding pulse calculations. However, these often perform worse in the implementation of the desired target magnetization or, in extreme cases, even fail to achieve the desired added value of the dynamic pulses.

### BRIEF DESCRIPTION AND SUMMARY

The scope of the embodiments is defined solely by the appended claims and is not affected to any degree by the statements within this summary. The present embodiments may obviate one or more of the drawbacks or limitations in the related art. Independent of the grammatical term usage, individuals with male, female or other gender identities are included within the term.

Embodiments provide for accelerating the performance of a magnetic resonance measurement including multiple partial measurements.

A computer-implemented method for performing a magnetic resonance measurement including multiple partial measurements is provided, the multiple partial measurements including at least a first partial measurement and a second partial measurement. The first partial measurement is performed in a first period. The second partial measurement is performed after the first partial measurement, i.e. after the first period. The second partial measurement includes the use of an excitation pulse for the excitation of a magnetic resonance signal, for example an RF transmission pulse and/or gradient pulse. During the first period, at least part of a pulse calculation of the excitation pulse is performed.

Pulse calculation is already started during the first period so that the available time is put to better use compared to conventional methods in which pulse calculation for the subsequent partial measurement is only started after the end of a partial measurement.

Pulse calculation may be performed, for example, with a computing unit, for example a computer. The computing unit may have one or more processors and/or one or more memory modules.

The multiple partial measurements may be performed one after the other. The second partial measurement may for example be provided immediately after the first partial measurement. One or more further partial measurements are provided between the first partial measurement and the second partial measurement. The pulse calculation of the excitation pulse for the second partial measurement takes place at least partially during one or more preceding partial measurements, for example the first partial measurement.

The pulse calculation of the excitation pulse need not necessarily be completed in the first period, instead it may be started in the first period, i.e. during the performance of the first partial measurement, but only completed after the end of the first partial measurement. The pulse calculation takes place at least partially during the performance of the first partial measurement. Better use may thus be made of the available time.

The pulse calculation of the excitation pulse naturally does not exclude the calculation of possible further excitation pulses, for example simultaneously. For example, the second partial measurement includes the use of at least one further excitation pulse for the excitation of a magnetic resonance signal, for example an RF transmission pulse and/or gradient pulse, wherein at least part of a pulse calculation of the at least one further excitation pulse is performed during the first period.

The first partial measurement is a partial measurement preceding the second partial measurement. Thus, the second partial measurement is a partial measurement subsequent to the second partial measurement. The method does not exclude the magnetic resonance measurement including multiple preceding or first partial measurements and multiple corresponding multiple subsequent or second partial measurements for which, during the period of the preceding partial measurement or the first period, at least part of a pulse calculation of the excitation pulse of the subsequent or second partial measurement is performed.

The excitation pulse is, for example, defined by at least one pulse parameter, at least one calculation operation to determine the at least one pulse parameter being performed during the first period.

Each partial measurement includes a k-space sample. The pulse calculation may be performed at least partially simultaneously with a k-space sample of the first partial measurement.

Each partial measurement includes an excitation and/or receipt of magnetic resonance signals. The pulse calculation is performed at least partially simultaneously with an excitation and/or receipt of magnetic resonance signals for the first partial measurement.

Each partial measurement includes the acquisition of an image data set. The pulse calculation is performed at least simultaneously with the acquisition of an image data set of the first partial measurement.

Each partial measurement includes an application of a magnetic resonance sequence. The pulse calculation is performed at least partially while a magnetic resonance sequence is used for the first partial measurement. A magnetic resonance sequence includes an array of multiple sequence modules, e.g. one or more excitation pulses, one or more gradient pulses and/or one or more readout modules. A partial measurement takes at least 10, for example at least 15, seconds.

One embodiment of the method provides for the excitation pulse to be a dynamic pulse, for example a pTx pulse. Dynamic pulses are often very time-consuming to calculate, so that an at least partial calculation during one or more preceding partial measurements has a favorable effect on the overall measurement time.

For example, an RF transmission pulse may be regarded as a dynamic pulse whose phase and/or amplitude changes over the course of time of the pulse, while a gradient trajectory, for example a predetermined gradient trajectory, is scanned by a gradient coil unit of the magnetic resonance apparatus. For example, the gradient trajectory is scanned in time with the variation in phase and/or amplitude of the RF transmission pulse.

The entirety of the RF transmission pulse and gradient trajectory may be a dynamic pulse. The RF transmission pulse is then part of the dynamic pulse.

“pTx” stands for “parallel transmission”. A pTx pulse may include multiple partial pulses that are transmitted in parallel, for example simultaneously, by a respective transmission coil of a radio frequency antenna unit of the magnetic resonance apparatus. Each transmission coil may in turn be assigned a transmission channel. The partial pulses may differ, for example in their shape and/or amplitude and/or phase. Furthermore, the partial pulses may have a time delay in relation to one another. For example, an emittable RF transmission pulse consists of multiple partial pulses that differ from one another and may each be transmitted by a transmission coil of a multichannel transmission coil arrangement of the radio frequency antenna unit. At least some of the multiple partial pulses, for example all the partial pulses, are dynamic pulses.

A dynamic pulse may control the B1 field generated thereby more precisely; such control may be used in applications with a reduced field of view, shaped saturation bands or to reduce the specific absorption rate (SAR). For example, magnetic field inhomogeneities may be compensated with a pTx pulse (for example, as part of “RF shimming”), that may be used above all at higher field strengths of the main magnetic field from 7 Tesla upwards.

When transmitting a dynamic pulse, for example a pTx pulse, a predetermined spatial distribution of the excitation may be achieved as an additional degree of freedom by interference of the signals of the plurality of transmission channels via a plurality of transmission coils of the radio frequency antenna unit, that is set when determining the dynamic pulse, for example by varying the phase and amplitude.

The at least one shape and/or amplitude and/or phase of the RF transmission pulse or a partial pulse may, for example, correspond to a shape and/or amplitude and/or phase of a voltage pulse that is applied to the respective transmission coil, and/or a current pulse that flows through the transmission coil.

The at least one shape and/or amplitude and/or phase of the gradient pulse may, for example, correspond to a shape and/or amplitude and/or phase of a voltage pulse that is applied to the gradient coil unit, and/or a current pulse that flows through the gradient coil unit.

One embodiment of the method provides that the multiple partial measurements are compiled in a measuring queue, the pulse calculation starting as soon as the second partial measurement (with the excitation pulse to be calculated) is added to the measuring queue.

For example, the measuring queue may be a sequence of the partial measurements that for example includes the first and the second partial measurement. For example, the measuring queue may be created by an operator of the magnetic resonance system. For example, the measuring queue may be a measuring waiting line.

A change to a partial measurement already present in the measuring queue may be regarded as synonymous with the addition of the partial measurement. A change to a second partial measurement (already present) may therefore be regarded as synonymous with the addition of a (new) second partial measurement. The calculation is started as soon as the information required for the calculation is available.

For example, the second partial measurement may be added by an operator of the magnetic resonance system. The addition of the second partial measurement provides information by which the pulse calculation may be performed. For example, such information includes the field of view (FOV), the slice orientation and/or the slice coverage (for example the number of slices, the slice spacing and/or the slice thickness) of the partial measurement concerned. Furthermore, such information may include at least one B0 card and/or at least one B1 card.

By immediately starting the pulse calculation as soon as the second partial measurement is added to the measuring queue, optimal use may be made of the time available.

One embodiment of the method provides that the pulse calculation includes multiple calculation iterations, wherein the calculation iterations are only completed when the partial measurement immediately preceding the second partial measurement is completed and/or a threshold value describing a quality of the calculated excitation pulse is reached and/or a convergence measure is reached.

For example, a calculation iteration may be a calculation iteration step. The excitation pulse may be (generally speaking) improved with an increasing number of calculation iterations performed. A subsequent calculation iteration (initially) may provide a poorer excitation pulse, but the generated excitation pulse converges to an optimum excitation pulse as it progresses.

The threshold value for example describes a measurement for a sufficient quality of the excitation pulse. For example, the sufficient quality may be defined in advance. If the quality of the excitation pulse is already “good enough”, it is possible to dispense with further calculation iterations.

For example, the convergence measure describes a convergence of a measurement for the quality of the excitation pulse with an increasing number of calculation iterations. With each calculation iteration, a value of the measurement for the quality of the excitation pulse is added to a sequence as a sequence element. Convergence occurs for example when this sequence comes arbitrarily close to a limit value in such a way that almost all sequence elements are located in every environment of the limit value. If the quality of the excitation pulse “no longer (significantly) improves” with even more calculation iterations, it is possible to dispense with further calculation iterations.

One embodiment of the method provides that a remaining time, for example an estimated remaining time, until the scheduled start of the second partial measurement is determined, for example estimated, a number of calculation iterations of the pulse calculation and/or a quality measurement of the pulse calculation being defined using the remaining time as a boundary condition for the pulse calculation.

The remaining time is a length of time remaining until the scheduled start of the second partial measurement. The remaining time includes, for example, a length of time that is required to complete the first partial measurement and, if necessary, to perform any further partial measurements between the first partial measurement and the second partial measurement and, if necessary, for any measurement pauses. The scheduled start may therefore be influenced for example by the position of the second partial measurement in the measuring queue.

The remaining time may be determined for example by empirical values and/or a simulation of the partial measurement or partial measurements. For example, the remaining time may be calculated with the aid of the repetition times of the magnetic resonance sequences that are performed for the partial measurement or partial measurements.

A higher number of calculation iterations and/or a higher quality measurement may be determined with a long remaining time. A better excitation pulse may be determined as a result.

The quality measurement includes a spatial and/or spectral resolution of the excitation pulse. For example, the quality measurement includes the spatial resolution of target magnetization that should be generated by the excitation pulse.

One embodiment of the method provides that the pulse calculation of the excitation pulse is performed for potential measurement parameters of the second partial measurement. Calculation data for potential measurement parameters is then already available even before such a measurement parameter is actually set. Such calculation data may be preliminary data, on the basis of which the final excitation pulse has yet to be calculated, or the final excitation pulse for one or more potential measurement parameters. The pulse calculation may already be started if, for example, the second partial measurement has not yet been (completely) set, but it has already been created in the measuring queue. Even if there is already a (provisional) parameterization of a partial measurement to be performed (e.g. second partial measurement), a pulse calculation may be performed for potential measurement parameters that could be set by changing the parameterization.

For example, partial measurements have already been created in the measuring queue for various measurement orientations (e.g. sagittal, transverse, coronal), but these have not yet been completed or finally parameterized. The pulse calculation is then started even before this (final) parameterization. Possible, i.e. potential, measurement parameters for partial measurements still to be performed according to the measuring queue (e.g. second partial measurement) may be anticipated.

For example, the potential measurement parameters of the second partial measurement have not yet been determined at the time of pulse calculation, i.e. they are speculative measurement parameters that may possibly still be discontinued (but also perhaps not). Measurement parameters that have a (relatively) high probability of actually (still) being set are selected as potential measurement parameters of the second partial measurement. A setting prediction may be carried out for this purpose, that is used to determine the potential measurement parameters. The setting prediction may, for example, be based on empirical values. For example, measurement parameters that are typically set by an operator (for example according to empirical values) may be selected as potential measurement parameters.

One embodiment of the method provides that the potential measurement parameters relate to a measuring range, for example a slice orientation and/or a slice coverage. For example, the measurement parameters may be used to set a measuring range, for example a slice orientation and/or a slice coverage, of the second partial measurement.

A pulse calculation for an increased coverage volume may be started before the second partial measurement is completely set. For example, coverage of the pulse calculation, for example in-plane and in the direction of the slice, may be increased compared to the current setting so that the final area to be covered (including a possible change in the current setting) is included with high probability. A pulse calculation may be performed for a greater number of slices.

Furthermore, a magnetic resonance apparatus is provided that is configured to carry out a method described above. The embodiments of the magnetic resonance apparatus essentially correspond to the embodiments of the method for performing a magnetic resonance measurement including multiple partial measurements, that are explained in detail in advance. Features, advantages or alternative embodiments may also be transferred to the other and vice versa.

Furthermore, a computer program product is provided that includes a program and may be loaded directly into a memory of a programmable system control unit of a magnetic resonance apparatus and has program resources, e.g. libraries and auxiliary functions, to perform a the provided method when the computer program product is executed in the system control unit of the magnetic resonance apparatus. The computer program product may include software with a source code that still needs to be compiled and linked or that only needs to be interpreted, or an executable software code that only needs to be loaded into the system control unit for execution.

The method may be executed in a fast, identically repeatable and robust manner by the computer program product. The computer program product is configured in such a way that it may perform the method steps by the system control unit. In each case, the system control unit has the prerequisites such as, for example, a corresponding memory, a corresponding graphic card or a corresponding logic unit so that the respective method steps may be performed efficiently.

The computer program product is, for example, saved on a computer-readable medium or stored on a network or server, from where it may be loaded into the processor of a local system control unit that is directly connected to the magnetic resonance apparatus or may be configured as part of the magnetic resonance apparatus. Furthermore, control information of the computer program product may be stored on an electronically readable data carrier. The control information of the electronically readable data carrier may be configured in such a way that it performs a proposed method when the data carrier is used in a system control unit of a magnetic resonance apparatus.

Examples of electronically readable data carriers are a DVD, a magnetic tape or a USB stick on which electronically readable control information, for example software, is stored. When this control information is read by the data carrier and saved in a system control unit of the magnetic resonance apparatus, the embodiments of the method described above may be carried out.

### BRIEF DESCRIPTION OF THE FIGURES

FIG. 1 depicts a diagrammatic view of a magnetic resonance apparatus according to an embodiment.

FIG. 2 depicts a flow chart of a computer-implemented method for performing a magnetic resonance measurement including multiple partial measurements according to an embodiment.

FIG. 3 depicts a first diagram of a multipart magnetic resonance measurement according to an embodiment.

FIG. 4 depicts a second diagram of a multipart magnetic resonance measurement according to an embodiment.

FIG. 5 depicts a third diagram of a multipart magnetic resonance measurement according to an embodiment.

FIG. 6 depicts a quality curve dependent on a number of iteration steps according to an embodiment.

FIG. 7 depicts a diagram of a precautionary extension of a measurement cover according to an embodiment.

### DETAILED DESCRIPTION

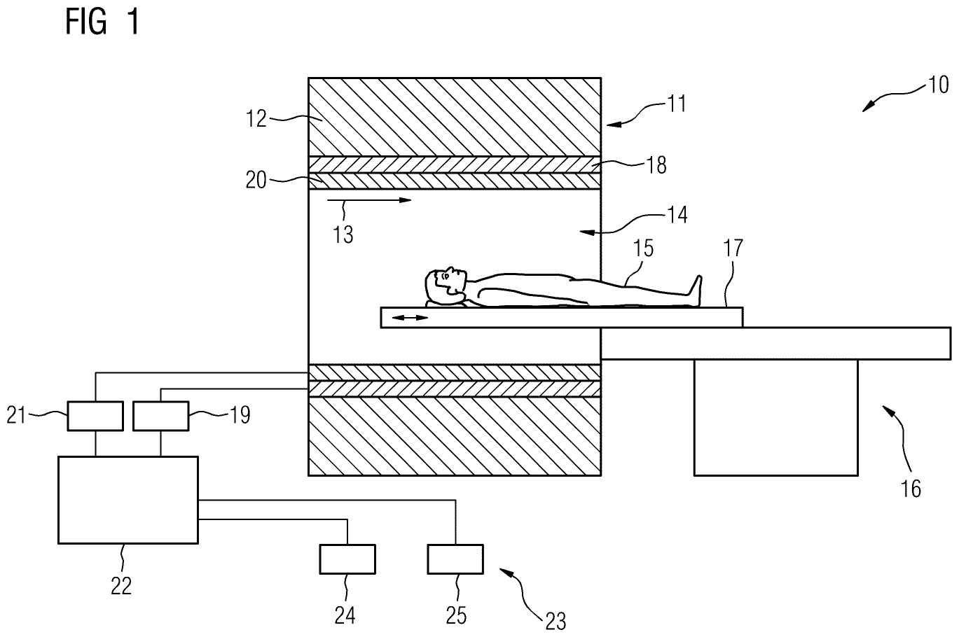

FIG. 1 depicts a diagrammatic view of a magnetic resonance apparatus 10. The magnetic resonance apparatus 10 includes a magnetic unit 11 that includes a main magnet 12 for the generation of a strong and for example temporally constant main magnetic field 13. In addition, the magnetic resonance apparatus 10 includes a patient receiving area 14 for receiving a patient 15. The patient receiving area 14 in this embodiment is cylindrical in design and cylindrically surrounded by the magnetic unit 11 in a circumferential direction. A different design of the patient receiving area 14 may be used. The patient 15 may be pushed into the patient receiving area 14 by a patient positioning device 16 of the magnetic resonance apparatus 10. The patient positioning device 16 includes a patient table 17 for this purpose that is configured to be movable within the patient receiving area 14.

The magnetic unit 11 also has a gradient coil unit 18 for the generation of gradient pulses that are used for location coding during imaging. The gradient coil unit 18 is controlled by a gradient control unit 19 of the magnetic resonance apparatus 10. The magnetic unit 11 also includes a radio frequency antenna unit 20, that in the present embodiment is configured as a body coil permanently integrated into the magnetic resonance apparatus 10. The radio frequency antenna unit 20 is controlled by a radio frequency antenna control unit 21 of the magnetic resonance apparatus 10 and emits RF transmission pulses into an examination area during a magnetic resonance measurement, that is essentially formed by a patient receiving area 14 of the magnetic resonance apparatus 10. As a result, the main magnet field 13 generated by the main magnet 12 is excited by atomic nuclei, that is why the radiated RF transmission pulses, for example in combination with gradient pulses adapted thereto, may also be referred to as excitation pulses. Magnetic resonance signals are generated by relaxation of the excited atomic nuclei. The radio frequency antenna unit 20 is configured to receive magnetic resonance signals.

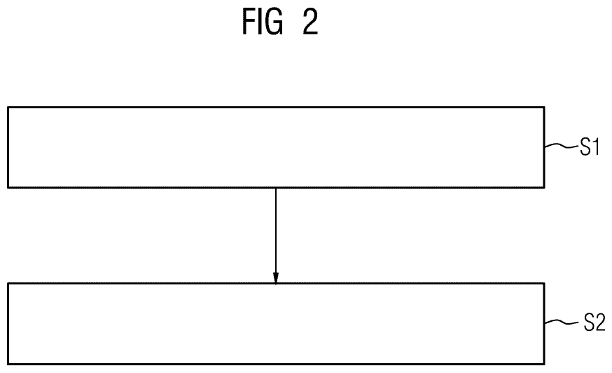

The magnetic resonance apparatus 10 has a system control unit 22 for controlling the main magnet 12, the gradient control unit 19 and for controlling the radio frequency antenna control unit 21. The system control unit 22 centrally controls the magnetic resonance apparatus 10, such as, for example, performing a predetermined imaging magnetic resonance measurement. The system control unit 22 is configured to execute a computer-implemented method for performing a magnetic resonance measurement including multiple partial measurements, as shown in FIG. 2. The system control unit 22 is configured to perform at least one part of a pulse calculation of an excitation pulse.

In addition, the system control unit 22 includes an evaluation unit not shown in more detail for evaluating the magnetic resonance signals that are recorded during the magnetic resonance examination. Furthermore, the magnetic resonance apparatus 10 includes a user interface 23 that is connected to the system control unit 22. Control information such as, for example imaging parameters, as well as reconstructed magnetic resonance images may be displayed on a display unit 24, for example on at least one monitor, the user interface 23 for a medical operator. Furthermore, the user interface 23 has an input unit 25 by which information and/or parameters may be entered by the medical operator during a measurement process.

FIG. 2 shows a diagrammatic flow chart of a computer-implemented method for performing a magnetic resonance measurement including multiple partial measurements. The multiple partial measurements include at least one first partial measurement and one second partial measurement. In S1, the first partial measurement is performed in a first period. In S2, the second partial measurement is performed after the first partial measurement. The second partial measurement includes the use of an excitation pulse, for example an RF transmission pulse and/or gradient pulse, for the excitation of a magnetic resonance signal. At least part of a pulse calculation of the excitation pulse is performed during the first period. For example, the excitation pulse may be a dynamic pulse, for example a pTx pulse. The method is used in this case as such calculations are very time-consuming and the examination time may be reduced with the method. Ideally, the waiting time for the pulse calculation may be reduced to zero by completing the calculation of pulses, for example excitation pulses, from partial measurements already set during the preceding measurement.

For example, the method provides that as soon as a subsequent partial measurement using an excitation pulse to be calculated, for example a dynamic pulse, has been set—that is to say, for example, when the operator clicks on an “Apply” button of the user interface 23—and at least one preceding partial measurement has not yet been completed, the pulse calculation for the subsequent partial measurement is started. The pulse calculation thus results in reduced downtime, or at best no downtime.

As the processing time is short in relation to customary measurement times, in many cases the calculation of the pulse is completed long before the end of the preceding measurement. Therefore, in a further aspect, the pulse calculation duration is extended to the available duration (i.e. until the planned start of the partial measurement with an excitation pulse to be calculated, for example a dynamic pulse) and this additional time is used to improve the pulse. This may be done by increasing the number of iterations that are provided for the pulse calculation, for example by selecting a higher spatial accuracy of the target magnetization or a higher spectral accuracy of the pulse profile for the pulse calculation, by dispensing with a combination of multiple slices in the case of multislice measurement, or by applying further improvements to the excitation pulse known to the person skilled in the art.

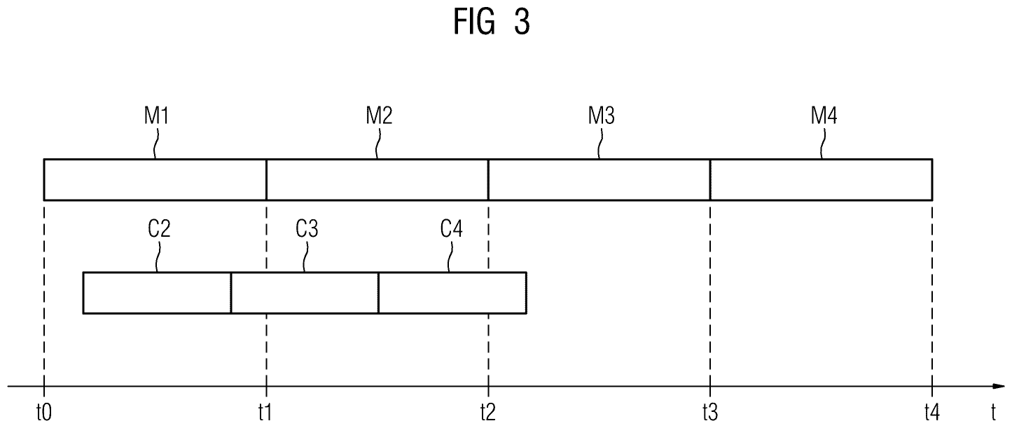

FIG. 3 depicts a diagrammatic view of a magnetic resonance measurement as a function of the time t with, in this example, four partial measurements M1, M2, M3, M4. The first partial measurement starts at the time 10 and ends at the time t1. These times 10 and t1 delimit a first period in which the first partial measurement is performed. A second partial measurement M2 is performed between the times t1 and t2, a third partial measurement M3 is performed between the times t2 and t3, and a fourth partial measurement M4 is performed between the times t3 and t4. The partial measurements M2, M3, M4 each provide for the application of at least one excitation pulse.

In this example, a pulse calculation C2 of an excitation pulse of the second partial measurement M2 is already started before the first partial measurement M1 is connected, i.e. before the time t1. The result is that this excitation pulse is already present when the second partial measurement M2 is started. Immediately after the pulse calculation C2, a pulse calculation C3 is started for an excitation pulse that is to be applied in a partial measurement M3. Immediately after the pulse calculation C3, a pulse calculation C4 is started for an excitation pulse that is to be applied in a partial measurement M4. The pulse calculation for excitation pulses of subsequent partial measurements therefore takes place during periods in which preceding partial measurements are still being performed. In this example, the excitation pulses are therefore calculated one after the other. However, they may also be calculated in whole or in part in parallel.

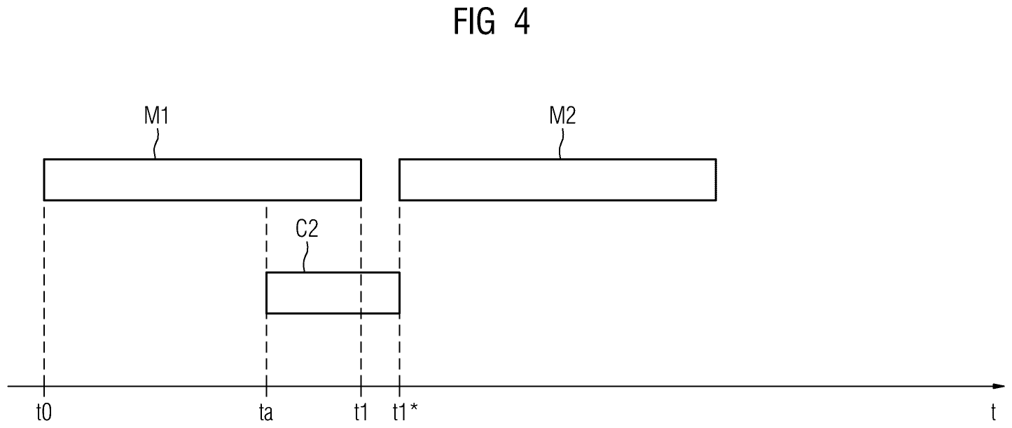

The multiple partial measurements are compiled in a measuring queue, the pulse calculation starting as soon as the second partial measurement is added to the measuring queue. This case is depicted in FIG. 4. After the partial measurement M1 has already started at subpoint t0, the partial measurement M2 of the measuring queue is added to the time ta. Then the pulse calculation for the excitation pulse of the partial measurement M2 also starts. In this example, the calculation is not completed within the first period, i.e. before t1, but takes until the time t1*. (During the first period only part of a pulse calculation of the excitation pulse is therefore performed.) Thereupon, the partial measurement M2 starts.

The partial measurement M2 may be added, for example by the operator of the magnetic resonance apparatus 10. The operator may use, for example, the user interface 23 for this purpose.

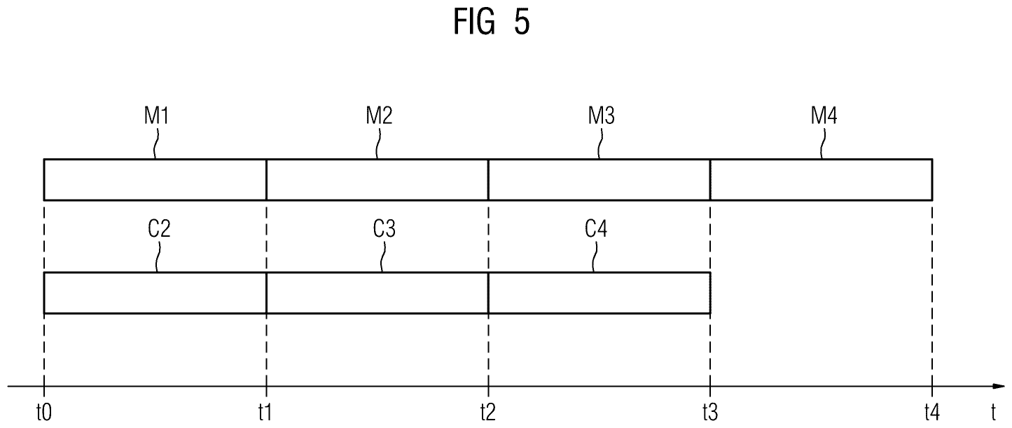

FIG. 5 depicts a variant of the method according to which the pulse calculation is performed until the start of the partial measurement in which the calculated excitation pulse is used. Thus, for example, the pulse calculation of the excitation pulse for the second partial measurement M2 lasts until the time t1, i.e. the start of the second partial measurement M2 and/or the end of the first partial measurement M1.

The pulse calculation includes multiple calculation iterations, the calculation iterations only being terminated when the partial measurement immediately preceding the second partial measurement M2 (i.e. here the first partial measurement) has been completed. In this case, the end of the preceding partial measurement is therefore the termination criterion for the iterative calculation. The time available until the end of the preceding measurement may be fully utilized by further refining the pulse iteratively, so that at best the result may still be improved.

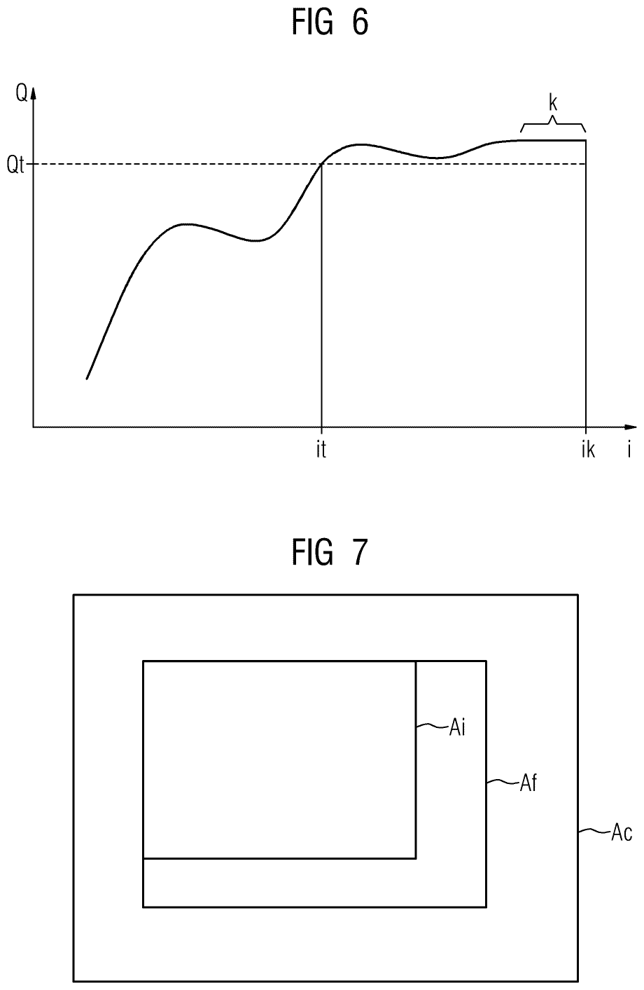

The calculation iterations may be completed when a threshold value describing a quality of the calculated excitation pulse is reached and/or a convergence measure is reached. This will be explained in more detail with reference to FIG. 6.

Here, an achieved quality Q is shown as a function of the number of calculation iterations i. After the calculation iteration it, a predetermined quality threshold value Qt is achieved, that may be used as a termination criterion. The quality threshold value Qt ensures that the excitation pulse calculated up to that point is sufficiently good.

The convergence of the quality Q with increasing calculation iterations i may also be used as an alternative or supplementary termination criterion; if, for example, the quality Q no longer changes significantly within a certain number of consecutive calculation iterations, as in this case in the k range, the pulse calculation may be terminated, as in this case after the calculation iteration ik.

According to one possible embodiment, a remaining time is determined until the scheduled start of the second partial measurement, a number of calculation iterations of the pulse calculation and/or a quality measurement of the pulse calculation being determined using the remaining time as a boundary condition for the pulse calculation. The quality measurement may, for example, be a spatial and/or temporal resolution of the excitation pulse.

In the case of FIG. 5, the remaining time for calculating the excitation pulse for the partial measurement M2 may be approximately the period from t0 to t1. This remaining time may be used to estimate how many calculation iterations are possible within this period in order to optimize the calculation process. The greater the remaining time, the more calculation iterations and the higher the spatial and/or temporal resolution of the excitation pulse are possible.

Furthermore, the pulse calculation of the excitation pulse may be performed for potential measurement parameters of the second partial measurement. The potential measurement parameters may relate, for example, to a measuring range, for example a slice orientation and/or a slice coverage. This is explained in FIG. 7 using the example of a measuring range. For example, according to a measurement protocol for magnetic resonance measurement, it is initially intended to measure a measuring range Ai with the second partial measurement. If sufficient time is available, the time until the start of the second partial measurement M2 may be used not only to perform the pulse calculation for the measuring range Ai, but also to perform the pulse calculation for a larger measuring range Ac as a precaution. If the parameterization of the second partial measurement, for example the size of the measuring range, is still to be changed, it is advantageous to fall back on this calculation data generated as a precaution. If, for example, the (initial) measuring range Ai is extended to include the (final) measuring range Af, ideally it is possible to dispense with additional calculations.

It is to be understood that the elements and features recited in the appended claims may be combined in different ways to produce new claims that likewise fall within the scope of the present embodiments. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present embodiments have been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method for performing a magnetic resonance measurement comprising multiple partial measurements, wherein the multiple partial measurements comprise at least a first partial measurement and a second partial measurement, the method comprising:
performing the first partial measurement in a first period, wherein during the first period at least part of a pulse calculation of an excitation pulse is performed; and
performing the second partial measurement after the first partial measurement, wherein the second partial measurement comprises a use of the excitation pulse for an excitation of a magnetic resonance signal.

2. The method of claim 1, wherein the excitation pulse comprises an RF transmission pulse or a gradient pulse.

3. The method of claim 1, wherein the excitation pulse is a dynamic pulse.

4. The method of claim 3, wherein the dynamic pulse is a pTx pulse.

5. The method of claim 1, wherein the multiple partial measurements are compiled in a measuring queue, wherein the pulse calculation starts as soon as the second partial measurement of the measuring queue is added.

6. The method of claim 1, wherein the pulse calculation comprises multiple calculation iterations, wherein the calculation iterations are only terminated when the partial measurement immediately preceding the second partial measurement is terminated, a threshold value describing a quality of the calculated excitation pulse is reached, or a convergence measure is reached.

7. The method of claim 1, further comprising:
determining a remaining time until a scheduled start of the second partial measurement, wherein a number of calculation iterations of the pulse calculation and/or a quality measurement of the pulse calculation is defined with reference to the remaining time as a boundary condition for the pulse calculation.

8. The method of claim 7, wherein the quality measurement comprises a spatial and/or temporal resolution of the excitation pulse.

9. The method of claim 1, wherein the pulse calculation of the excitation pulse is performed for potential measurement parameters of the second partial measurement.

10. The method of claim 9, wherein the potential measurement parameters relate to a measuring range.

11. The method of claim 10, wherein the measuring range comprises a slice orientation or a slice coverage.

12. A magnetic resonance apparatus comprising:
a main magnet configured for generation of a strong and temporally constant main magnetic field;
a gradient coil unit configured for generation of gradient pulses that are used for location coding during imaging;
a radio frequency antenna unit configured to emit RF transmission pulses into an examination area during a magnetic resonance measurement; and
a system control unit configured to control the main magnet, the gradient coil unit, and the radio frequency antenna unit, the system control unit configured to perform the magnetic resonance measurement comprising multiple partial measurements, wherein the multiple partial measurements comprise at least a first partial measurement and a second partial measurement, wherein the first partial measurement is performed in a first period, wherein during the first period at least part of a pulse calculation of an excitation pulse is performed, wherein the second partial measurement is performed after the first partial measurement, wherein the second partial measurement comprises the use of the excitation pulse for an excitation of a magnetic resonance signal.

13. The magnetic resonance apparatus of claim 12, wherein the excitation pulse comprises an RF transmission pulse or a gradient pulse.

14. The magnetic resonance apparatus of claim 12, wherein the excitation pulse is a dynamic pulse.

15. The magnetic resonance apparatus of claim 14, wherein the dynamic pulse is a pTx pulse.

16. The magnetic resonance apparatus of claim 12, wherein the multiple partial measurements are compiled in a measuring queue, wherein the pulse calculation starts as soon as the second partial measurement of the measuring queue is added.

17. The magnetic resonance apparatus of claim 12, wherein the pulse calculation comprises multiple calculation iterations, wherein the calculation iterations are only terminated when the partial measurement immediately preceding the second partial measurement is terminated, a threshold value describing a quality of the calculated excitation pulse is reached, or a convergence measure is reached.

18. A non-transitory computer implemented storage medium, including machine-readable instructions stored therein for performing a magnetic resonance measurement comprising multiple partial measurements, wherein the multiple partial measurements comprise at least a first partial measurement and a second partial measurement, the instructions when executed by at least one processor, cause the processor to:
perform the first partial measurement in a first period, wherein during the first period at least part of a pulse calculation of an excitation pulse is performed; and
perform the second partial measurement after the first partial measurement, wherein the second partial measurement comprises a use of the excitation pulse for an excitation of a magnetic resonance signal.

19. The non-transitory computer implemented storage medium of claim 18, wherein the instructions further cause the processor to:
determine a remaining time until a scheduled start of the second partial measurement, wherein a number of calculation iterations of the pulse calculation and/or a quality measurement of the pulse calculation is defined with reference to the remaining time as a boundary condition for the pulse calculation.

20. The non-transitory computer implemented storage medium of claim 19, wherein the quality measurement comprises a spatial and/or temporal resolution of the excitation pulse.
